(19) United States
(12) Patent Application Publication
(10) Pub. No.: US 2013/0092553 A1
(43) Pub. Date: Apr. 18, 2013

(54) SUPPLY SYSTEM AND SUPPLY METHOD FOR FUNCTIONAL SOLUTION

(71) Applicants: Haruyoshi Yamakawa, Tokyo (JP); Minoru Uchida, Tokyo (JP); Toru Otsu, Tokyo (JP)

(72) Inventors: Haruyoshi Yamakawa, Tokyo (JP); Minoru Uchida, Tokyo (JP); Toru Otsu, Tokyo (JP)

(73) Assignee: Kurita Water Industries Ltd., Tokyo (JP)

(21) Appl. No.: 13/259,848

(22) PCT Filed: Mar. 16, 2010
(86) PCT No.: PCT/JP2010/054440

§ 371 Date: Oct. 21, 2011

(30) Foreign Application Priority Data
Mar. 24, 2009 (JP) 2009-071718
Feb. 25, 2010 (JP) 2010-040905

(51) Int. Cl. H01L 21/02; C25B 9/00; C25B 1/22

(52) U.S. Cl. CPC H01L 21/02041; C25B 1/22; C25B 9/00
USPC 205/471; 204/237

(57) ABSTRACT

Provided are an electrolyzing unit (electrolyzing device 1) that electrolyzes a sulfuric acid solution having a sulfuric acid concentration of 75 to 96% by weight to generate peroxosulfuric acid, a gas-liquid separation unit (gas-liquid separation tank 10) that subjects the sulfuric acid solution thus electrolyzed to gas-liquid separation, a circulation line 11 that causes a portion of the sulfuric acid solution subjected to gas-liquid separation in the gas-liquid separation unit to circulate between it and the electrolyzing unit, a supply line 20 that supplies a portion of the sulfuric acid solution subjected to gas-liquid separation in the gas-liquid separation unit to an application side (single-wafer cleaning device 100), and a heating unit 22 that is provided in the supply line 20 and heats the sulfuric acid solution to 120 to 190° C., in which a transit time after the sulfuric acid solution is introduced to an inlet of the heating unit until being used in the application side is set so as to be less than 1 minute.

### TECHNICAL FIELD

The present invention relates to a functional solution supply system and supply method that can be suitably used in the cleaning of resist adhered to electronic materials such as silicon wafers, and enables the supply of a functional solution obtained by electrolyzing sulfuric acid to an application side that performs cleaning of the resist and the like.

### BACKGROUND ART

It is necessary for the resist adhered to electronic materials such as silicon wafers in the semiconductor manufacturing process and the like to subsequently be stripped and removed from the electronic materials due to becoming unneeded. A solution, conventionally used for resist stripping, is a mixture of concentrated sulfuric acid and hydrogen peroxide, so called SPM. In a stripping process using SPM, there are drawbacks in that the running cost is high since sulfuric acid and hydrogen peroxide are consumed in large quantity, and further a large quantity of waste liquid is discharged.

Addressing this, the present inventors have developed and proposed a cleaning method and cleaning system that use, as cleaning liquid, an electrolyzed sulfuric acid solution containing an oxidizing substance such as peroxosulfuric acid, which is composed of peroxodisulfuric acid and peroxomonosulfuric acid obtained by electrolyzing sulfuric acid, in the stripping of the resist, and cyclically uses the electrolyzed sulfuric acid solution used in cleaning by electrolyzing again (Patent Literature 1 and 2). According to these cleaning systems, high cleaning effect is obtained simultaneously with reducing the amount of cleaning solution used and the waste liquid amount.

### CITATION LIST

### Patent Literature

[PATENT LITERATURE 1] Japanese Patent Application Publication No. 2006-114880
[PATENT LITERATURE 2] Japanese Patent Application Publication No. 2006-278687

### SUMMARY OF THE INVENTION

### Technical Problem

By the way, accompanying LSI miniaturization in recent years, the amount of ion implanted to the electronic materials such as silicon wafers is on the rise. In the fabrication process of electronic circuits, the same amount of ion is implanted also in the resist that becomes unwanted in subsequent processing and will be stripped and removed. However, when the amount of ion implantation increases, it becomes difficult to strip the unwanted resist from the electric materials. In the SPM processing in particular, when the ion dosing amount is 1×10¹⁵ atoms/cm² or more, it becomes difficult to completely strip the resist. As a result, it is necessary to perform an ashing treatment by way of oxygen plasma or the like called ashing, as a pre-processing.

On the other hand, in batch processing by way of an electrolyzed sulfuric acid solution, although stripping of resist without performing ashing is possible, in a case of cleaning resist with an increased amount of ion implantation, there is a problem in that the throughput declines due to the longer time needed for resist stripping.

It should be noted that, as a method of cleaning electronic materials and the like, there is single-wafer type in addition to the batch type. In the single-wafer type, the cleaning target is fixed to a rotating table, and this is cleaned by spraying a chemical while rotating, for example. However, the constitution of single-wafer cleaning devices is not limited thereto, and may be the device constitution disclosed in Japanese Patent Application Publication No. 2004-172493 or Japanese Patent Application Publication No. 2007-266495, for example. In a single-wafer cleaning device, it is possible to effectively strip unwanted resist from an electronic material such as a silicon wafer with relatively small amount of chemical used. As the chemical used in the single-wafer cleaning device, it is possible to use an electrolyzed sulfuric acid solution containing an oxidizing substance such as peroxosulfuric acid generated by an oxidation reaction at the anode by way of electrolysis of sulfuric acid, similarly to the batch type. In addition, the amount of waste liquid generated in stripping and cleaning of resist can be reduced in the single-wafer cleaning device as well, by using a solution supply system that can repeatedly recover the electrolyzed sulfuric acid solution used in the stripping, electrolyzes the recovered solution, and supply to the single wafer cleaning device again.

However, characteristics with even stricter requirements than the electrolyzed sulfuric acid solution used in a batch-type cleaning device are demanded for the chemicals used in the single-wafer cleaning devices. In particular, a functional solution possessing higher peroxosulfuric acid concentration and higher liquid temperature is demanded in the stripping and cleaning of resist ion implanted at a high concentration of 1×10¹⁵ atoms/cm² or higher. However, since the self-decomposition rate is extremely high when peroxosulfuric acid is at high temperature, it is difficult to supply a functional solution simultaneously satisfying the high peroxosulfuric acid concentration and high liquid temperature with a conventional functional solution supply system.

The present invention has been made taking into account of the above-mentioned circumstances, and has an object of providing a functional solution supply system and supply method that can supply a functional solution simultaneously satisfying high peroxosulfuric acid concentration and high liquid temperature, to an application side.

### Means for Solving Problem

More specifically, according to a first aspect of the present invention, a functional solution supply system of the present invention includes: an electrolyzing unit that electrolyzes a sulfuric acid solution having a sulfuric acid concentration of 75 to 96% by weight to generate peroxosulfuric acid; a gas-liquid separation unit that subjects the sulfuric acid solution thus electrolyzed to gas-liquid separation; a circulation line that causes a portion of the sulfuric acid solution subjected to gas-liquid separation in the gas-liquid separation unit to circulate via the electrolyzing unit to the gas-liquid separation unit; a supply line that supplies a portion of the sulfuric acid solution subjected to gas-liquid separation in the gas-liquid separation unit to an application side; and a heating unit that is provided in the supply line and heats the sulfuric acid solution to 120 to 190° C. to make a functional solution, in which a transit time after the sulfuric acid solution is introduced to an inlet of the heating unit until being used at the application side is set so as to be less than 1 minute.

According to the second aspect of a functional solution supply system, in the first aspect of the present invention, the electrolyzing unit may be constituted to be diaphragm-free type.

According to the third aspect of a functional solution supply system, in the first aspect of the present invention, the electrolyzing unit may be constituted to be diaphragm type, the gas-liquid separation unit may be connected to an anode side of the electrolyzing unit, and a cathode-side gas-liquid separation unit may be connected to a cathode side of the electrolyzing unit.

According to the fourth aspect of a functional solution supply system, in any one of the first to third aspects of the present invention, the gas-liquid separation unit may also function as a retention unit that accumulates sulfuric acid solution.

According to the fifth aspect of a functional solution supply system, any one of the first to third aspects of the present invention may further include a retention unit that accumulates the sulfuric acid solution subjected to gas-liquid separation in the gas-liquid separation unit, in which the circulation line may perform the circulation of the sulfuric acid solution accumulated in the retention unit.

According to the sixth aspect of a functional solution supply system, in the fifth aspect of the present invention, the supply line may perform the supply of the sulfuric acid solution accumulated in the retention unit.

According to the seventh aspect of a functional solution supply system, any one of the first to fourth aspects of the present invention may further include: a recirculation line that causes sulfuric acid drainage discharged after use in the application side to recirculate to either one or both the gas-liquid separation unit and the electrolyzing unit; and a cooling unit that is provided in the recirculation line and cools the sulfuric acid drainage.

According to the eighth aspect of a functional solution supply system, the fifth or sixth aspect of the present invention may further include: a recirculation line that causes sulfuric acid drainage discharged after use in the application side to recirculate to either one or both the retention unit and the electrolyzing unit; and a cooling unit that is provided in the recirculation line and cools the sulfuric acid drainage.

According to the ninth aspect of a functional solution supply system, in the seventh or eighth aspect of the present invention, a decomposition unit that causes the sulfuric acid drainage to be retained and acts to decompose residual organic matter contained in the sulfuric acid drainage may be provided on an upstream side of the cooling unit in the recirculation line.

According to the tenth aspect of a functional solution supply system, in any one of the first to ninth aspects of the present invention, a heat source of the heating unit may be a near-infrared heater.

According to the eleventh aspect of a functional solution supply system, in the tenth aspect of the present invention, the near-infrared heater may be disposed so as to irradiate near-infrared rays in a thickness direction relative to a flow channel having a thickness of no more than 10 mm that communicates the sulfuric acid solution, and to heat the sulfuric acid solution by way of radiant heat.

According to the twelfth aspect of a functional solution supply system, in any one of the first to eleventh aspects of the present invention, the application side may be a single-wafer cleaning system.

According to the thirteenth aspect of a functional solution supply method of the present invention, electrolysis is performed while circulating and subjecting a sulfuric acid solution having a sulfuric acid concentration of 75 to 96% by weight to gas-liquid separation, and a portion of the sulfuric acid solution thus electrolyzed is supplied to an application side after being removed and heated to a temperature of 120 to 190° C., such that a time after initiating the heating until reaching use is less than 1 minute.

That is, according to the present invention, it is possible to supply a functional solution containing peroxosulfuric acid to an application side such as a single-wafer cleaning device, in a high-temperature state with the peroxosulfuric acid maintained at high concentration. This functional solution has a strong oxidative power from the peroxosulfuric acid contained in this solution self-decomposes upon utilization at the application side, and can achieve a high stripping cleaning effect even for a resist ion implanted at high concentration, for example.

In the present invention, the sulfuric acid concentration of the sulfuric acid solution is set at 75 to 96% by weight, and peroxosulfuric acid is generated by electrolyzing this sulfuric acid solution. When the sulfuric acid concentration is lower than 75% by weight, although there are advantages such as the current efficiency (peroxosulfuric acid production per unit current amount) rising, the liquid temperature cannot be raised enough since the boiling point lowers, and the cleaning effect such as stripping of resist lowers. In addition, when the sulfuric acid concentration exceeds 96% by weight, the liquid temperature can be raised due to the boiling point rising. However, the generation efficiency of peroxosulfuric acid declines during electrolysis when the sulfuric acid concentration is high, the concentration of peroxosulfuric acid becomes insufficient, and the cleaning effect such as stripping of resist lowers. For these reasons, the sulfuric acid concentration of the sulfuric acid solution is established in said range. In addition, it is desirable to set the lower limit of the sulfuric acid concentration to 80% by weight and the upper limit thereof to 92% by weight for similar reasons.

The sulfuric acid solution is electrolyzed in an electrolyzing unit, whereby peroxosulfuric acid is generated. As the electrodes employed in electrolysis, among the anode and cathode, it is desirable to establish at least the anode as a conductive diamond electrode. At this time, at least a wetted part functioning as the anode may be made of conductive diamond. Furthermore, it is very desirable if both electrodes are established as conductive diamond electrodes. Since the conductive diamond has high chemical stability and large potential window, it is known that the conductive diamond is suitable for electrode material for generating peroxosulfuric acid from sulfuric acid solution (See Japanese Patent Application Publication No. 2001492874). An electrode on which a conductive thin film has been deposited on a base such as conductive Si or metal, or a plate-shaped electrode constituted by only conductive diamond without a base can be used as the constitution of the conductive diamond electrode. In addition, it may be constitute so that a plurality of electrodes that are not fed power are embedded between the anode and cathode which are fed power from a DC power supply, and electrolysis is performed by causing these to be bipolar. The electrodes for this bipolar can also be configured by the above-mentioned conductive diamond electrode.

A diaphragm-free electrolyzing device without a diaphragm such as an ion-exchange membrane between the electrodes, or a diaphragm-type electrolyzing device in which between the anode and cathode is partitioned by a diaphragm such as an ion-exchange membrane can be used as the above-mentioned electrolyzing unit. In the diaphragm-free electrolyzing device, an oxidizing substance such as peroxosulfuric acid generated in the anode reaction is lost due to reduction at the cathode, whereby the current efficiency declines. On the other hand, in the diaphragm-type electrolyzing device, since a gas-liquid separation unit and circulation line are required independently on both the anode side and cathode side, which are partitioned by the diaphragm, the configuration of the system becomes more complicated than the case of using a diaphragm-free electrolyzing device. However, due to the reduction of the oxidizing substance not occurring at the cathode, the current efficiency improves. It should be noted that the electrolyzing unit of the present invention is not limited to these specific constitutions, so long as being a constitution in which the sulfuric acid solution is electrolyzed to generate peroxosulfuric acid.

With the above-mentioned electrolyzing unit, the anode and cathode are arranged so as to be immersed in the sulfuric acid solution. The sulfuric acid solution is electrolyzed by flowing current between these electrodes, whereby sulfate ion in the sulfuric acid solution is oxidized to generate persulfate ion. At this time, oxygen gas evolves due to the anode reaction on the anode side and hydrogen gas evolves due to the cathode reaction on the cathode side.

In a case of being a diaphragm-free electrolyzing device, these gases will be mixed inside the electrolyzing device. Since this mixed gas has an explosive property, it is desirable for the sulfuric acid solution after electrolysis processing to be immediately fed through a circulation line to the gas-liquid separation unit to separate the gas. It is desirable for the separated gas to be diluted by gas such as nitrogen gas outside the present system, and safely processed such as being subjected to decomposition in a catalytic device.

On the other hand, in a case of being a diaphragm-type electrolyzing device, oxygen gas evolves in the electrolyzed sulfuric acid solution on the anode side, and mixes with the solution. In this gas-liquid mixed state, heating loss occurs in a heating unit described later; therefore, the oxygen gas is separated in the gas-liquid separation unit on the anode side prior to being fed to the heating unit. In addition, although hydrogen gas evolves on the cathode side and mixes in the solution, the hydrogen gas is separated by the gas-liquid separation unit on the cathode side, and is safely processed by a catalytic device or the like, for example.

In the gas-liquid separation unit, gas contained in the sulfuric acid solution fed from the electrolyzing unit is separated, and discharged to outside the present system. A discharge unit for discharging the gas can be provided in the gas-liquid separation unit. In addition, either or both a concentrated-sulfuric acid supply line that supplies concentrated sulfuric acid and a pure water supply line that supplies pure water can be connected to the gas-liquid separation unit. In addition, a retention unit can be provided on a downstream side of the gas-liquid separation unit, and one or both of the above-mentioned concentrated-sulfuric acid supply line and the above-mentioned pure water supply line can be connected to this retention unit.

During operation of the present system, the sulfuric acid solution concentration in the system varies according to electrolysis of the sulfuric acid solution, evaporation of water, moisture absorption, and the like. As a result, concentrated sulfuric acid or pure water may be supplied to the gas-liquid separation unit or retention unit from these supply lines, whereby the sulfuric acid concentration of the sulfuric acid solution circulating can be manipulated or controlled so as not to deviate from the range of 75 to 96% by weight.

Beside in the gas-liquid separation unit and retention unit, adjustment of the sulfuric acid concentration can be performed in a decomposition tank described later. A concentration tuning unit for adjusting the sulfuric acid concentration circulating may be provided in the circulation line at the upstream of the electrolyzing unit. It should be noted that it is desirable for a cooling unit to be provided in the circulation line in order to regulate the temperature of the sulfuric acid solution at the inlet of the electrolyzing unit.

Portion of the sulfuric acid solution from which gas has been separated by the gas-liquid separation unit is fed to the electrolyzing unit again, electrolyzed and circulated to the gas-liquid separation unit by the circulation line. The sulfuric acid solution can be raised in peroxosulfuric acid concentration by performing electrolysis while performing gas-liquid separation as well as causing to circulate. The other portion of the sulfuric acid solution is fed through the supply line to an application side. It should be noted that, when the electrolyzing unit is established as a diaphragm-type electrolyzing device, the supply line is provided so as to be in communication with a cathode side gas-liquid separation unit.

With the above-mentioned gas-liquid separation unit, it is desirable for the above-mentioned sulfuric acid solution to be able to be temporarily retained, and in this case, the gas-liquid separation unit also has a function as a retention unit.

It may be a constitution equipped with a retention unit other than the above-mentioned gas-liquid separation unit. This retention unit connects to a downstream side of the gas-liquid separation unit. The circulation line and/or supply line may be configured so as to connect to this retention unit and circulate and/or supply thereto.

It should be noted that, although the cleaning effect increases with higher liquid temperature of the sulfuric acid solution, the oxidizing substance with the peroxosulfuric acid contained in the liquid as a main constituent quickly decomposes and disappears. On the other hand, when the liquid temperature of the sulfuric acid solution is low, the cleaning effect such as stripping of resist will lower even if the oxidizing substance is adequately contained therein. As a result, moderate heating is required when feeding the sulfuric acid solution after electrolysis to the application side.

Therefore, a heating unit for heating the sulfuric acid solution is provided in the supply line. This heating unit heats the sulfuric acid solution containing peroxosulfuric acid to produce the functional solution. It should be noted that the heating unit is set so as to heat the temperature of the sulfuric acid solution to the range of 120° C. to 190° C. In a case of the temperature being less than 120° C., the effects such as of stripping the resist in the application side will not be sufficient because the oxidizing power of the functional solution produced will not be sufficient. If the temperature exceeds 190° C., most of the peroxosulfuric acid will be lost before being supplied to the application side due to the self-decomposition rate of peroxosulfuric acid being too high. As a result, the temperature of the functional solution to be heated by the heating unit is set to the above-mentioned range. Furthermore, it is desirable to set the lower limit of the temperature to 130° C.

It should be noted that, in order to raise the temperature while maintaining the oxidizing substance contained in the sulfuric acid solution at a high concentration, it is desirable to rapidly heat in as short a time as possible.

As for the constitution of the heating unit, it may be any constitution that can heat the sulfuric acid solution to the above temperature range, and furthermore, a constitution that heats in one pass manner is desirable. It should be noted that the heating unit constitution of the present invention is not limited to a specific constitution, and it is desirable to use a near-infrared heater as the heat source. If a near-infrared heater is established as the heat source, the sulfuric acid solution does not become high temperature locally as at a heat transfer surface in convection heating, because the heating target is uniformly and rapidly heated by radiant heat without there being a heat transfer surface between the heat source and the heating target. As a result, heat can be uniformly transferred to the entirety of the sulfuric acid solution, and the temperature can be raised efficiently. In addition, the problem of the decomposition of the peroxosulfuric acid being promoted due to local high temperatures is also eliminated. It should be noted that a heater irradiating near-infrared rays with a wavelength on the order of 0.7 to 3.0 μm can be exemplified as the near-infrared heater.

Furthermore, it is desirable for the near-infrared heater to irradiate a flow channel preferably made of quartz, having a liquid communication space with a thickness of no more than 10 mm that passes the sulfuric acid solution therethrough. If established with such a constitution, the sulfuric acid solution passing through the narrow flow channel can be more uniformly and rapidly heated. If the thickness of the flow channel exceeds 10 mm, it will become difficult to uniformly heat the sulfuric acid solution flowing in the flow channel using the radiant heat of the near-infrared heater.

It should be noted that the oxidizing substance with peroxosulfuric acid as the main constituent is contained in the functional solution produced in the heating unit, the self-decomposition rate of this oxidizing substance will gradually speed up by being heated. As a result, the oxidizing power of the functional solution is gradually lost with the passing of time, whereby the stripping and cleaning effect relative to the cleaning target material such as electronic materials on which a resist is formed will also gradually decrease.

In the present invention, the passage time from the initiation of heating of the sulfuric acid solution until being used at the application side is set to less than 1 minute. Furthermore, it is more desirable to set the passage time to within 30 seconds. If set in this way, the functional solution can be supplied for use in the application side while maintaining high oxidizing power, before decomposition of the oxidizing substance such as peroxosulfuric acid progresses. If the passage time is 1 minute or more, most of the oxidizing substance contained in the functional solution will disappear, and it will be difficult to achieve sufficient function at the application side.

In order to set the passage time to less than 1 minute, the sulfuric acid solution flow rate may be set relative to the volume of the fluid communication channel from the inlet of the heating unit to a position used in the application side so as to pass therethrough in less than 1 minute, for example. In addition, the volume of the fluid communication channel may be set relative to the flow rate of the sulfuric acid solution set in advance so that the retention time is less than 1 minute. Furthermore, the flow rate and volume may be controlled variably.

The functional solution produced is supplied through the supply line to the application side such as a single-wafer cleaning device, for example. Although there is not a particular limitation for the flow rate of the functional solution supplied to the application side, it is desirable to set a flow rate of 350 to 2000 m liter/min. per one cleaning target such as a silicon wafer, and furthermore, it is very desirable to set to 500 to 2000 m liter/min. Although it is preferable to increase the flow rate as the cleaning target material becomes larger, the cleaning effect will not be enhanced even if set to a flow rate exceeding 2000 m liter/min per each one cleaning target, and thus is not preferable because the required energy in the production of the functional solution will increase. It should be noted that, although an explanation has been provided herein with the application side as a single-wafer cleaning device, the application side of the present invention is not to be limited to a specific device or system.

In the application side, after a cleaning target such as electronic substrate materials has been cleaned or the like, sulfuric acid drainage of relative high temperature is discharged. In the present invention, a recirculation line can be provided that causes this sulfuric acid drainage to recirculate in the system. By connecting the recirculation line to at least one or more among the gas-liquid separation unit, the retention unit and the electrolyzing unit, it is possible to make the sulfuric acid drainage recirculate in the present system.

In order to keep the liquid temperature of the gas-liquid separation unit and retention unit and the liquid temperature of the electrolyzing unit inlet at predetermined temperatures, a cooling unit is provided in the recirculation line. Solid residue of the resist generated in the application side that cannot be decomposed with the functional solution, for example, is contained in the sulfuric acid solution recirculated by the recirculation line. A filter can be provided in the recirculation line in order to remove this residue. It is possible to install the filter on the upstream side or downstream side of the cooling unit, or at the heating unit inlet side of the supply line, and a plurality of these filters may be established.

A decomposition unit, which causes sulfuric acid drainage received from the application side to be retained and carries out decomposition of residual organic matter such as resist stripped from electronic substrate material and contained in the sulfuric acid drainage, can be provided in the recirculation line on an upstream side of the above-mentioned cooling unit. The oxidizing substance such as peroxosulfuric acid resides in the sulfuric acid drainage, and the resist and the like in the sulfuric acid drainage made to retain in the decomposition unit is oxidatively decomposed and removed by the action of the oxidizing substance using the remaining heat of the sulfuric acid drainage. This oxidative decomposition becomes more effective with higher temperatures. Therefore, it is desirable to retain the heat in the decomposition unit in order to effectively use the remaining heat of the sulfuric acid drainage recirculated from the application side. The constitution of the decomposition unit may be any constitution that can accelerate decomposition of residual organic matter such as resist contained in the sulfuric acid drainage, and a decomposition tank of a structure retaining sulfuric acid drainage can be exemplified, for example.

Similarly to the aforementioned gas-liquid separation unit, either one or both of a concentrated-sulfuric acid supply line and a pure water supply line can be provided to the decomposition unit. By supplying concentrated sulfuric acid or pure water from these supply lines to the decomposition tank, it is possible to regulate the sulfuric acid concentration of the decomposition tank to a predetermined range. According to this configuration, the stability of the present system operation can be further improved because the sulfuric acid concentration of the sulfuric acid drainage recirculated to either one or both the gas-liquid separation unit and the electrolyzing unit can be regulated.

A drainage line that removes the sulfuric acid drainage recirculated from the application side to outside of the present system without feeding to the decomposition unit can be provided in the recirculation line. By providing such a drainage line, for example, it is possible to control so that the sulfuric acid drainage is discharged to outside the system through the drainage line without feeding to the decomposition unit, when the amount of stripped resist in the sulfuric acid drainage is remarkably abundant such as immediately after cleaning initiation, and so that the above-mentioned sulfuric acid drainage is fed to the decomposition unit at a stage at which the amount of stripped resist has fallen. Therefore, the drainage line is required to be connected to the recirculation line at an upstream side of the decomposition unit. In addition to the load of residual organic matter decomposition in the decomposition unit being reduced by the above-mentioned configuration, for example, the load of the present system can be reduced because SS (solid suspended particles) generated immediately after cleaning can be discharged to outside the system without processing with a filter or the like inside the system. Therefore, in a case of providing a filter in the recirculation line, it is desirable for the drainage line to be connected to the recirculation line at an upstream side of the filter.

It should be noted that liquid of high stripped resist concentration that is discharged from the drainage line may be subjected to waste liquid treatment by mixing with the drainage generated by another process or the like, for example.

### Effects of the Invention

As explained in the foregoing, according to the present invention, it is possible to supply a functional solution containing peroxosulfuric acid to an application side in a high-temperature state with the peroxosulfuric acid maintained at high concentration. Therefore, even in a case the application side having strict cleaning conditions such as those of a single-wafer cleaning device, it is possible to satisfactorily strip and clean even resist that had been ion implanted at a high concentration formed on an electronic material surface such as a silicon wafer, liquid crystal glass substrate, and photomask substrate.

### BRIEF DESCRIPTION OF DRAWINGS

FIG. 1 is a schematic diagram showing an embodiment of a functional solution supply system of the present invention;

FIG. 2 is an enlarged view showing a configuration of a heating unit of the same;

FIG. 3 is a schematic diagram showing a system according to another embodiment of the same;

FIG. 4 is a schematic diagram showing a system according to yet another embodiment of the same;

FIG. 5 is a schematic diagram showing a system according to yet another embodiment of the same;

FIG. 6 is a schematic diagram showing a system according to yet another embodiment of the same; and

FIG. 7 is a schematic diagram from a heater until reaching a nozzle outlet in the system according to the embodiment of the same.

### DESCRIPTION OF EMBODIMENTS

### First Embodiment

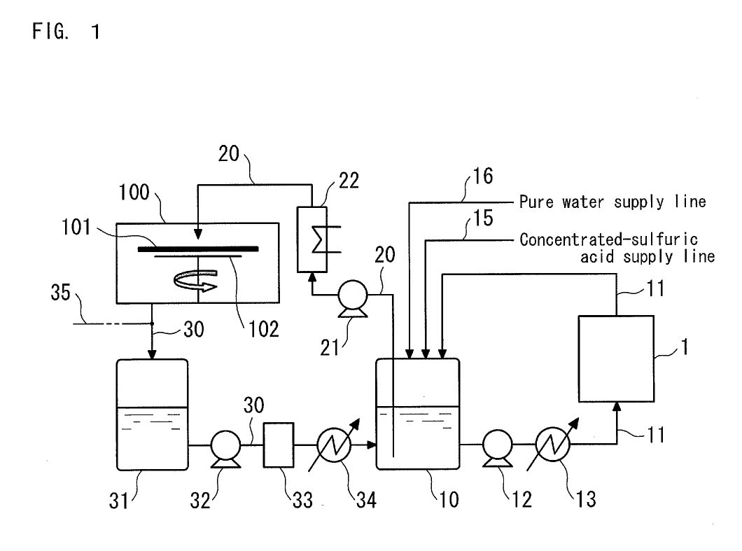

Hereinafter, an embodiment of a functional solution supply system of the present invention is explained based on FIG. 1. This embodiment is a system constitution in a case of an electrolyzing unit being constituted by a diaphragm-free electrolyzing device.

An electrolyzing device 1 corresponding to the electrolyzing unit of the present invention is of diaphragm-free type, with the anode and cathode (not illustrated) constituted by diamond electrodes being arranged inside without being separated by a diaphragm, and a DC power source that is not illustrated being connected to both the electrodes.

A gas-liquid separation tank 10 corresponding to a gas-liquid separation unit of the present invention is connected to the above-mentioned electrolyzing device 1 via a circulation line 11 to enable liquid communication for circulation. The gas-liquid separation tank 10 holds a sulfuric acid solution containing gas, and separates and discharges the gas in the sulfuric acid solution to outside the system, and so long as enabling gas-liquid separation in the present invention, a well-known tank can be used, with the constitution thereof not being particularly limited.

A circulation pump 12 that causes the sulfuric acid solution in the gas-liquid separation tank 10 to circulate, and a cooler 13 that cools the sulfuric acid solution are provided in the circulation line 11 positioned between a drainage side of the above-mentioned gas-liquid separation tank 10 and an inlet side of the electrolyzing device 1. The cooler 13 corresponds to a cooling unit of the present invention, and so long as it can cool the sulfuric acid solution to an appropriate temperature, the constitution thereof is not particularly limited in the present invention. It should be noted that a discharge side of the electrolyzing device 1 and an inlet side of the gas-liquid separation tank 10 are connected by the circulation line 11 to enable liquid communication.

A concentrated-sulfuric acid supply line 15 and a pure water supply line 16 are connected to the gas-liquid separation tank 10, which enable concentrated sulfuric acid or pure water to be appropriately supplied into the gas-liquid separation tank 10.

Furthermore, a supply line 20 capable of taking out sulfuric acid solution in the gas-liquid separation tank 10 is connected to the gas-liquid separation tank 10, and a single-wafer cleaning device 100 corresponding to an application side of the present invention is provided to a supply end of the supply line 20. A solution feed pump 21 that feeds the sulfuric acid solution in the gas-liquid separation tank 10, and a heating unit 22 that heats the sulfuric acid solution fed by the solution feed pump 21 are provided in the supply line 20 in sequence at an upstream side of the single-wafer cleaning device 100.

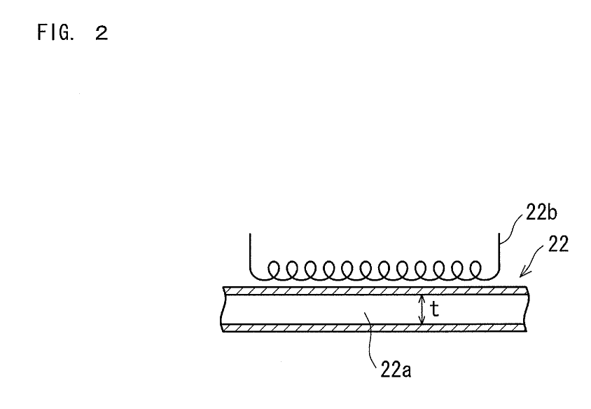

As shown in FIG. 2, the heating unit 22 has a flow channel 22a having a liquid communication space made of quartz with a thickness (t) of no more than 10 mm, and a near-infrared heater 22b that is arranged so as to irradiate near-infrared rays in the thickness direction onto the flow channel 22a, and thus is able to heat the sulfuric acid solution by one pass, passing through the flow channel 22a using the near-infrared heater 22b. The near-infrared heater 22b can irradiate near-infrared rays within the range of wavelengths of 0.7 to 3.0 μm.

One end of a recirculation line 30 drawing in the sulfuric acid solution discharged from cleaning of a cleaning target and causing to circulate to the gas-liquid separation tank 10 is connected to the single-wafer cleaning device 100, and a decomposition tank 31 corresponding to a decomposition unit of the present invention is provided in the recirculation line 30. At a downstream side of the decomposition tank 31, a solution return pump 32 that feeds sulfuric acid drainage retained in the decomposition tank 31, a filter 33 that collects SS contained in the sulfuric acid drainage and removes it from the sulfuric acid drainage, and a cooler 34 that cools the sulfuric acid solution are provided in sequence in the recirculation line 30. At the downstream side thereof, the other end side of the recirculation line 30 is connected to the gas-liquid separation tank 10. The cooler 34 corresponds to a cooling unit of the present invention, and so long being able to cool the sulfuric acid solution to an appropriate temperature, the constitution thereof is not particularly limited in the present invention.

Next, operation (supply method) of a functional solution supply system composed of the above-mentioned configuration will be explained.

A sulfuric acid solution having a sulfuric acid concentration of 75 to 96% by weight is retained in the gas-liquid separation tank 10 so as to be able to be supplied through the circulation line 11 to the electrolyzing device 1. In other words, the gas-liquid separation tank 10 also has a function as a storage tank that retains sulfuric acid solution. The sulfuric acid solution is fed by the circulation pump 12, is regulated to a temperature suited for electrolysis by the cooler 13, and is introduced to an inlet side of the electrolyzing device 1. In the electrolyzing device 1, electric current passes between the anode and cathode by way of a DC power source, which is not illustrated, and the sulfuric acid solution introduced into the electrolyzing device 1 is electrolyzed. It should be noted that, in the electrolyzing device 1, oxygen gas evolves along with an oxidizing substance including peroxosulfuric acid being generated at the anode side, and hydrogen gas evolves at the cathode side, by way of the electrolysis. This oxidizing substance and gasses are sent through the recirculation line 11 to the gas-liquid separation tank 10 in a state mixed with the sulfuric acid solution, and the gas is separated. It should be noted that the gas is discharged outside of the present system and is safely processed by way of a catalytic device (not illustrated) or the like.

The sulfuric acid solution from which the gas has been separated by the gas-liquid separation tank 10 contains peroxosulfuric acid, and furthermore, is repeatedly sent through the circulation line 11 to the electrolysis device 1, whereby the concentration of peroxosulfuric acid is raised by electrolysis. When the peroxosulfuric acid concentration becomes moderate, a portion of the sulfuric acid solution in the gas-liquid separation tank 10 is fed through the supply line 20 to the heating unit 22 by way of the supply pump 21.

In the heating unit 22, the sulfuric acid solution containing peroxosulfuric acid is heated while passing through the flow channel 22a to a range of 120° C. to 190° C. by the near-infrared heater 22b to make the functional solution. Then, the functional solution is supplied through the supply line 20 to the single-wafer cleaning device 100, and used in the cleaning as a chemical. At this time, the flow rate of the functional solution is regulated so that the transit time from the inlet of the heating unit 22 until used in the single-wafer cleaning device 100 is less than 1 minute. It should be noted that, in the single-wafer cleaning device 100, a flow rate of 500 to 2,000 m liter/min. is defined as an adequate amount, and the length and flow-channel cross-sectional area of the flow channel 22a of the heating unit 22, and the line length and flow channel cross-section area of the supply line 20 on a downstream side thereof etc. are set so that the transit time is less than 1 minute at this flow rate.

In the single-wafer cleaning device 100, for example, with a silicon wafer 101 on which an ion-implanted resist at a high concentration of 1×10¹⁵ atoms/cm² or more is provided as the cleaning target, the resist is effectively stripped and removed by making the silicon wafer 101 rotate on a rotating table 102 while coming into contact with the above-mentioned functional solution.

The functional solution used in cleaning is discharged from the single-wafer cleaning device 100 as sulfuric acid drainage, and is retained through the recirculation line 30 in the decomposition tank 31. Residual organic matter such as the resist cleaned in the single-wafer cleaning device 100 is contained in the sulfuric acid drainage, and the residual organic matter is oxidatively decomposed while retained in the decomposition tank 31 by the oxidizing substance contained in the sulfuric acid drainage. It should be noted that the residence time of the sulfuric acid drainage in the decomposition tank 31 can be arbitrarily adjusted according to the content such as of residual organic matter or the like. At this time, by making the decomposition tank 31 able to keep the heat, it is possible to make oxidative decomposition using the residual heat of the sulfuric acid drainage reliable. In addition, it is also possible to provide a heating device to the composition tank 31 as desired.

The sulfuric acid drainage in which the oxidizing substance has been oxidatively decomposed contained in the decomposition tank 31 is recirculated by the solution return pump 32 to the gas-liquid separation tank 10 through the filter 33 and cooler 34 provided in the recirculation line 30. At this time, SS that had not been processed in the decomposition tank 31 is collected and removed by the filter 33. When a high temperature sulfuric acid drainage is recirculated to the gas-liquid separation tank 10, decomposition of peroxosulfuric acid in the sulfuric acid solution retained in the gas-liquid separation tank 10 is promoted; therefore, the sulfuric acid drainage is introduced into the gas-liquid separation tank 10 after the sulfuric acid drainage is cooled by the cooler 34. The sulfuric acid drainage introduced into the gas-liquid separation tank 10 is fed to the electrolyzing device 1 by way of the circulation line 11 as sulfuric acid solution and peroxosulfuric acid is generated by electrolysis, and is then recirculated again to the gas-liquid separation tank 10 by the circulation line 11.

By the above-mentioned operation of present system, it is possible to continuously supply high temperature functional solution containing high-concentration peroxosulfuric acid to the single-wafer cleaning device 100, which is the application side.

It should be noted that, although not explained above, a drainage line 35 is connected to the recirculation line 30 on a upstream side of the decomposition tank 31 to branch therefrom, and it may be constituted so as to be able to drain the sulfuric acid drainage to outside the system without feeding to the decomposition tank 31 when appropriate.

The drainage line 35 allows the control such that when the amount of stripped resist in the sulfuric acid drainage immediately after cleaning begins is a considerably large amount, the burden on the decomposition tank 31 is reduced by discharging the sulfuric acid drainage to outside the system by way of the drainage line 35, and the above-mentioned sulfuric acid drainage is fed to the decomposition tank 31 at a stage at which the amount of stripped resist has dropped. This control can be performed by way of opening and shutting an on-off valve provided in the recirculation line or drainage line.

### Second Embodiment

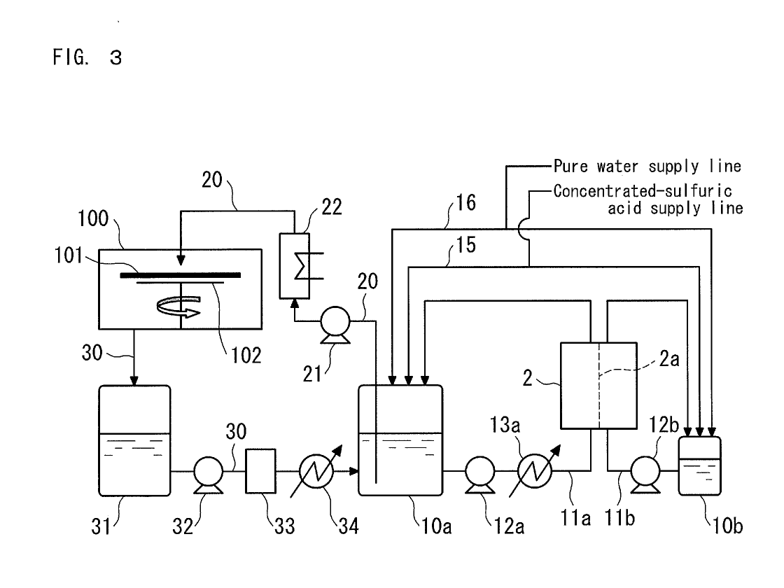

Next, another embodiment of a functional solution supply system of the present invention will be explained based on FIG. 3.

The second embodiment is a system constitution in a case of the electrolyzing unit being constituted by a diaphragm-type electrolyzing device. It should be noted that the same reference symbols are assigned in the second embodiment for constitution that are the same as the first embodiment, and explanations thereof are omitted or abbreviated.

An electrolyzing device 2 includes an anode and cathode (not illustrated) configured by diamond electrodes, and between this anode and cathode is divided by a diaphragm 2a. The anode side is connected in liquid communication via a circulation line 11a to be able to circulate with a gas-liquid separation tank 10a corresponding to a gas-liquid separation unit of the present invention, and the cathode side is connected in liquid communication via a circulation line 11b to be able to circulate with a gas-liquid separation tank 10b corresponding to a cathode-side gas-liquid separation unit of the present invention. Circulation pumps 12a and 12b, which respectively feed the sulfuric acid solution in the gas-liquid separation tanks 10a and 10b to an inlet side of the electrolyzing device 2, are provided in the circulation line 11a and circulation line 11b, respectively. In addition, a cooler 13a that cools the sulfuric acid solution is provided in the circulation line 11a of the anode side at a downstream side of the circulation pump 12a and an upstream side of the inlet side of the electrolyzing device 2, to serve as a device corresponding to the cooling unit of the present invention. It is thereby possible to regulate to a temperature suited to electrolysis by cooling the sulfuric acid solution on the anode side, which rises in temperature during electrolysis.

It should be noted that a concentrated-sulfuric acid supply line 15 and a pure water supply line 16 are connected to the gas-liquid separation tanks 10a and 10b to enable liquid communication, whereby it is possible to appropriately supply concentrated sulfuric acid and pure water to the gas-liquid separation tanks 10a and 10b.

The supply line 20 capable of taking out sulfuric acid solution in the gas-liquid separation tank 10a is connected to the gas-liquid separation tank 10a, and the single-wafer cleaning device 100 corresponding to the application side of the present invention is provided to a supply end of the supply line 20. A solution feed pump 21 that feeds the sulfuric acid solution in the gas-liquid separation tank 10a, and a heating unit 22 that heats the sulfuric acid solution fed by the solution feed pump 21 are provided in the supply line 20 in sequence at an upstream side of the single-wafer cleaning device 100.

Similarly to the first embodiment, the heating unit 22 has a flow channel 22a having a liquid communication space made of quartz with a thickness (t) of no more than 10 mm, and a near-infrared heater 22b that is arranged so as to irradiate near-infrared rays in the thickness direction onto the flow channel 22a.

One end of the recirculation line 30 is connected to the single-wafer cleaning device 100, and the decomposition tank 31, solution return pump 32, filter 33 and cooler 34 are provided in sequence in the recirculation line 30. At a downstream side thereof, the other end side of the recirculation line 30 is connected to the gas-liquid separation tank 10a.

Next, operation (supply method) of a functional solution supply system composed of the above-mentioned configuration will be explained.

A sulfuric acid solution having a sulfuric acid concentration of 75 to 96% by weight is retained in the gas-liquid separation tanks 10a and 10b so as to be able to be supplied through the circulation lines 11a and 11b to the electrolyzing device 2. The sulfuric acid solution is fed by the circulation pumps 12a and 12b, and is introduced through the circulation lines 11a and 11b to the inlet sides of the anode and cathode of the electrolyzing device 2. It should be noted that, after the sulfuric acid solution has been regulated to a temperature suited for electrolysis by the cooler 13a, it is introduced to the anode inlet side of the electrolyzing device 2 by the circulation line 11a. In the electrolyzing device 2, current is passed between the anode and cathode by a DC power source that is not illustrated, whereby the sulfuric acid solution introduced into the electrolyzing device 2 is electrolyzed. It should be noted that an oxidizing substance including peroxosulfuric acid and oxygen gas generate at the anode side, and hydrogen gas evolves at the cathode side in the electrolyzing device 2 by way of the electrolysis. The oxidizing substance and oxygen gas are sent through the circulation line 11a to the gas-liquid separation tank 10a in a state mixed with the sulfuric acid solution, and the oxygen gas is separated. The hydrogen gas is sent through the circulation line 11b to the gas-liquid separation tank 10b in a state mixed with the sulfuric acid solution, and the hydrogen gas is separated. It should be noted that each gas is discharged to outside of the present system and safely processed by a catalytic device (not illustrated) or the like.

The sulfuric acid solution from which the gas has been separated by the gas-liquid separation tank 10a contains peroxosulfuric acid, and furthermore, is repeatedly sent to the anode side of the electrolyzing device 2 through the circulation line 11a, whereby the concentration of peroxosulfuric acid is raised by electrolysis. When the peroxosulfuric acid concentration becomes moderate, a portion of the sulfuric acid solution in the gas-liquid separation tank 10a is fed through the supply line 20 to the heating unit 22 by way of the supply pump 21. The sulfuric acid solution for which the gas has been separated by the gas-liquid separation tank 10b is repeatedly sent through the circulation line 11b to the cathode side of the electrolyzing device 2, and is subjected to electrolysis.

In the heating unit 22, the sulfuric acid solution containing the peroxosulfuric acid is heated while passing through the flow channel 22a to a range of 120° C. to 190° C. by the near-infrared heater 22b to make the functional solution. The functional solution is supplied from the heating unit 22 through the supply line 20 to the single-wafer cleaning device 100. The flow rate of the functional solution is regulated so that the transit time from the inlet of the heating unit 22 until used in the single-wafer cleaning device 100 is less than 1 minute.

In the single-wafer cleaning device 100, with a silicon wafer 101 on which an ion-implanted resist at a high concentration is provided as the cleaning target similarly to the above-mentioned embodiment, the resist is effectively stripped and removed by making the silicon wafer 101 rotate on the rotating table 102 while coming into contact with the above-mentioned functional solution.

The functional solution used in cleaning is accumulated through the recirculation line 30 in the decomposition tank 31 as sulfuric acid drainage, and the residual organic matter is oxidatively decomposed in the decomposition tank 31.

The sulfuric acid drainage in which the residual organic matter has been oxidatively decomposed in the decomposition tank 31 is recirculated through the filter 33 and cooler 34 to the gas-liquid separation tank 10a by way of the solution return pump 32. At this time, SS (suspended solids) is collected and removed by the filter 33, and the sulfuric acid drainage is cooled by the cooler 34, then introduced into the gas-liquid separation tank 10a.

It is possible to continuously supply a high-temperature functional solution containing high-concentration peroxosulfuric acid to the single-wafer cleaning device 100, which is the application side, by the operation of this system as well.

### Third Embodiment

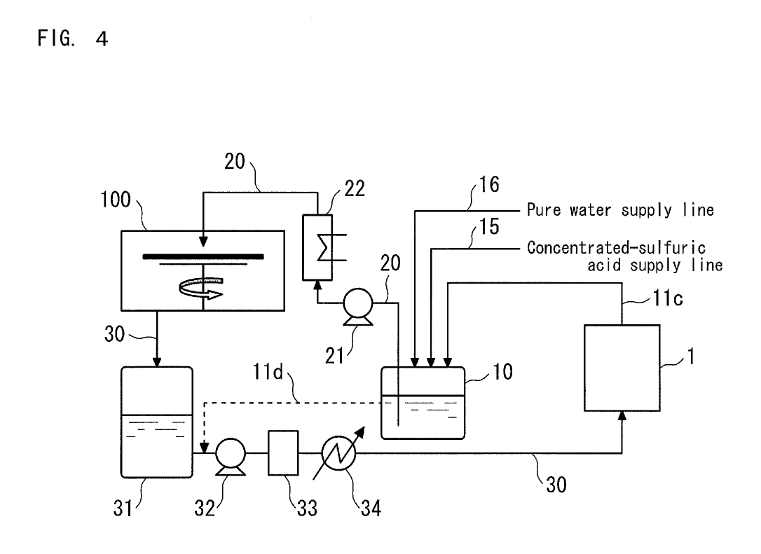

Next, another embodiment of a functional solution supply system of the present invention will be explained based on FIG. 4. This embodiment has a configuration in liquid communication from a decomposition tank directly to an electrolyzing device without passing through a gas-liquid separation tank. It should be noted that the same reference symbols are assigned in the third embodiment for configurations that are the same as the first or second embodiments, and explanations thereof are omitted or abbreviated.

In the present embodiment as well, the diaphragm-free electrolyzing device 1 is provided similarly to the first embodiment, and the anode and cathode configured by diamond electrodes are provided.

A gas-liquid separation tank 10 corresponding to a gas-liquid separation unit of the present invention is connected to enable liquid communication via a feed line 11c, corresponding to a portion of the circulation line, to an outlet side of the above-mentioned electrolyzing device 1.

One end of a return line 11d corresponding to a portion of the circulation line is connected to a drainage side of the above-mentioned gas-liquid separation tank 10, and the other end side of the return line 11d is connected so as to merge with the recirculation line 30 described later.

It should be noted that a concentrated-sulfuric acid supply line 15 and a pure water supply line 16 are connected to the gas-liquid separation tank 10, which enable concentrated sulfuric acid or pure water to be appropriately supplied into the gas-liquid separation tank 10.

Furthermore, a supply line 20 capable of taking out sulfuric acid solution in the gas-liquid separation tank 10 is connected to the tank, the solution feed pump 21 and the heating unit 22 that heats the sulfuric acid solution fed by the solution feed pump 21 are provided in sequence in the supply line 20, and the single-wafer cleaning device 100 is connected to downstream side thereof.

Similarly to the first embodiment, the heating unit 22 has a flow channel 22a having a liquid communication space made of quartz with a thickness (t) of no more than 10 mm, and a near-infrared heater 22b that is arranged so as to irradiate near-infrared rays in the thickness direction onto the flow channel 22a.

One end of the recirculation line 30 is connected to the single-wafer cleaning device 100, and the decomposition tank 31, solution return pump 32, filter 33 and cooler 34 are provided in sequence in the recirculation line 30. At a downstream side thereof, the other end side of the recirculation line 30 is connected to the inlet side of the electrolyzing device 1. The cooler 34 corresponds to a cooling unit of the present invention, and so long as it can cool the sulfuric acid solution to a suitable temperature, the constitution thereof is not particularly limited in the present invention.

The recirculation line 30 on a downstream side from the spot at which the return line 11d merges therewith constitutes the circulation line of the present invention in cooperation with the feed line 11c and return line 11d, thereby enabling the sulfuric acid solution to be circulated between the gas-liquid separation tank 10 and the electrolyzing device 1 while being electrolyzed.

Next, operation (supply method) of a functional solution supply system composed of the above-mentioned configuration will be explained.

A sulfuric acid solution having a sulfuric acid concentration of 75 to 96% by weight is retained in the gas-liquid separation tank 10 so as to be able to be supplied through the return line 11d and recirculation line 30 to the electrolyzing device 1. The sulfuric acid solution is fed by the solution return pump 32, and after having passed through the filter 33, is regulated to a temperature suited to electrolysis by the cooler 34 and introduced to the inlet side of the electrolyzing device 1. In the electrolyzing device 1, electric current passes between the anode and cathode by way of a DC power source, which is not illustrated, and the sulfuric acid solution introduced into the electrolyzing device 1 is electrolyzed. In the electrolyzing device 1, an oxidizing substance including peroxosulfuric acid as well as oxygen gas are generated at the anode side, and hydrogen gas evolves at the cathode side by way of the electrolysis. The oxidizing substance and gasses are sent through the feed line 11c to the gas-liquid separation tank 10 in a state mixed with the sulfuric acid solution, and the gas is separated.

The sulfuric acid solution from which the gas has been separated by the gas-liquid separation tank 10 contains peroxosulfuric acid, and a portion is repeatedly sent through the return line 11d and recirculation line 30 to the electrolyzing device 1, whereby the concentration of peroxosulfuric acid is raised by electrolysis. When the peroxosulfuric acid concentration becomes moderate, a portion of the sulfuric acid solution in the gas-liquid separation tank 10 is fed through the supply line 20 to the heating unit 22 by way of the supply pump 21.

The sulfuric acid solution fed to the heating unit 22 is heated to a range of 120° C. to 190° C. by the near-infrared heater 22b while passing through the flow channel 22a, and is supplied through the supply line 20 to the single-wafer cleaning device 100 as a functional solution. At this time, the flow rate of the functional solution is regulated so that the transit time from the inlet of the heating unit 22 until used in the single-wafer cleaning device 100 is less than 1 minute.

In the single-wafer cleaning device 100, a silicon wafer on which an ion-implanted resist at a high concentration is provided similar to the above-mentioned embodiment is cleaned with the functional solution, and the resist is effectively stripped and removed. The functional solution used in cleaning is retained through the recirculation line 30 in the decomposition tank 31 as sulfuric acid drainage, and the residual organic matter is oxidatively decomposed in the decomposition tank 31.

The sulfuric acid drainage in which the residual organic matter has been oxidatively decomposed in the decomposition tank 31 combines with the sulfuric acid solution fed from the gas-liquid separation tank 10 by way of the solution return pump 32 and is recirculated through the filter 33 and cooler 34 to the electrolyzing device 1 as sulfuric acid solution. At this time, SS is collected and removed by the filter 33, and the sulfuric acid solution is cooled by the cooler 34, then introduced into the electrolyzing device 1.

It is possible to continuously supply a high-temperature functional solution containing high-concentration peroxosulfuric acid to the single-wafer cleaning device 100, which is the application side, by the operation of this system as well.

### Fourth Embodiment

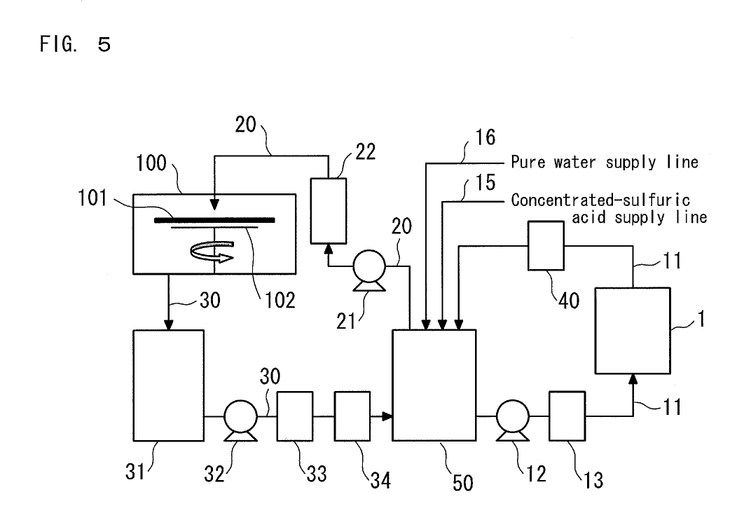

Each of the above-mentioned embodiments establishes a constitution communicating the sulfuric acid solution accumulated in a gas-liquid separation unit through a circulation line and supply line. However, the present invention may be constituted so as to include a retention tank in addition to the gas-liquid separation unit, and communicate the sulfuric acid solution via this retention tank by way of the circulation line and supply line. The fourth embodiment of this configuration will be explained hereinafter based on FIG. 5. It should be noted that the same reference symbols are assigned for configurations that are the same as the above-mentioned respective embodiments, and explanations thereof are omitted or abbreviated.

A gas-liquid separation tank 40 corresponding to a gas-liquid separation unit of the present invention is connected via the circulation line 11 to an outlet side of a diaphragm-free electrolyzing device 1 to enable liquid communication for circulation. A gas-liquid separation tank 40 accommodates a sulfuric acid solution containing gas, separates the gas in the sulfuric acid solution and discharges to outside the system, and any of well-known types of tank.

A retention tank 50 that accumulates sulfuric acid solution having undergone gas-liquid separation is connected by the circulation line 11 to a drainage side of the above-mentioned gas-liquid separation tank 40. The retention tank 50 corresponds to a retention unit of the present invention. In addition, the circulation line 11 further extends to a downstream side via the retention tank 50 and is connected to an inlet side of the electrolyzing device 1.

A circulation pump 12 that causes the sulfuric acid solution in the retention tank 50 to circulate and a cooler 13 that cools the sulfuric acid solution are provided in the circulation line 11 located between the retention tank 50 and the inlet side of the electrolyzing device 1. The cooler 13 corresponds to a cooling unit of the present invention, and so long as it can cool the sulfuric acid solution to a suitable temperature, the configuration thereof is not particularly limited in the present invention.

In addition, a concentrated-sulfuric acid supply line 15 and a pure water supply line 16 are connected to the retention tank 50, which enable concentrated sulfuric acid or pure water to be suitably supplied into the retention tank 50.

Furthermore, a supply line 20 capable of taking out sulfuric acid solution in the retention tank 50 is connected to the retention tank 50, and a single-wafer cleaning device 100 is provided to a supply end of the supply line 20. A solution feed pump 21 that feeds the sulfuric acid solution in the gas-liquid separation tank 10, and a heating unit 22 that heats the sulfuric acid solution fed by the solution feed pump 21 are provided in the supply line 20 in sequence at the upstream side of the single-wafer cleaning device 100.

One end of the recirculation line 30, which draws in the sulfuric acid solution discharged from cleaning of a cleaning target and causes to recirculate to the retention tank 50, is connected to the single-wafer cleaning device 100, and a decomposition tank 31 corresponding to a decomposition unit of the present invention is provided in the recirculation line 30. At a downstream side of the decomposition tank 31, a solution return pump 32 that feeds sulfuric acid drainage accumulated in the decomposition tank 31, a filter 33 that collects SS (suspended solids) contained in the sulfuric acid drainage and removes it from the sulfuric acid drainage, and a cooler 34 that cools the sulfuric acid solution are provided in sequence in the recirculation line 30. At the downstream side thereof, the other end side of the recirculation line 30 is connected to the retention tank 50.

Next, operation (supply method) of a functional solution supply system composed of the above-mentioned configuration will be explained.

A sulfuric acid solution having a sulfuric acid concentration of 75 to 96% by weight is accumulated in the retention tank 50 so as to be able to be supplied through the circulation line 11 to the electrolyzing device 1. The sulfuric acid solution is fed by the circulation pump 12, is regulated to a temperature suited for electrolysis by the cooler 13, is introduced to an inlet side of the electrolyzing device 1, and the sulfuric acid solution introduced into the electrolyzing device 1 is electrolyzed. It should be noted that, in the electrolyzing device 1, oxygen gas evolves along with an oxidizing substance including peroxosulfuric acid being generated at the anode side, and hydrogen gas is generated at the cathode side, by way of the electrolysis. This oxidizing substance and gasses are sent through the recirculation line 11 to the gas-liquid separation tank 40 in a state mixed with the sulfuric acid solution, and the gas is separated. It should be noted that the gas is discharged to outside of the present system and is safely processed by way of a catalytic device (not illustrated) or the like.

The sulfuric acid solution from which the gas has been separated by the gas-liquid separation tank 40 contains peroxosulfuric acid, and furthermore, is sent through the circulation line 11 to the retention tank 50. The sulfuric acid solution in the retention tank 50 is repeatedly sent to the electrolyzing device 1, whereby the concentration of peroxosulfuric acid is raised by electrolysis. When the peroxosulfuric acid concentration becomes moderate, a portion of the sulfuric acid solution in the retention tank 50 is fed through the supply line 20 to the heating unit 22 by way of the supply pump 21.

In the heating unit 22, the sulfuric acid solution containing peroxosulfuric acid is heated while passing through the flow channel 22a to a range of 120° C. to 190° C. by the near-infrared heater 22b to make the functional solution. Then, the functional solution is supplied through the supply line 20 to the single-wafer cleaning device 100, and used in the cleaning as a chemical. At this time, the flow rate of the functional solution is regulated so that the transit time from the inlet of the heating unit 22 until used in the single-wafer cleaning device 100 is less than 1 minute.

In the single-wafer cleaning device 100, as mentioned above, the silicon wafer 101 is the cleaning target, and the resist is effectively stripped and removed by making the silicon wafer 101 rotate on a rotating table 102 while coming into contact with the above-mentioned functional solution.

The functional solution used in cleaning is discharged from the single-wafer cleaning device 100 as sulfuric acid drainage, and is accumulated through the recirculation line 30 in the decomposition tank 31. The residual organic matter is oxidatively decomposed while accumulated in the decomposition tank 31 by the oxidizing substance contained in the sulfuric acid drainage. It should be noted that the residence time of the sulfuric acid drainage in the decomposition tank 31 can be arbitrarily adjusted according to the content such as of residual organic matter or the like. At this time, by making the decomposition tank 31 able to keep the heat, it is possible to make oxidative decomposition using the waste heat of the sulfuric acid drainage reliable. In addition, it is also possible to provide a heating device to the decomposition tank 31 as desired.

The sulfuric acid drainage in which the oxidizing substance has been oxidatively decomposed contained in the decomposition tank 31 is recirculated by the solution return pump 32 to the retention tank 50 through the filter 33 and cooler 34 provided in the recirculation line 30. At this time, SS (suspended solids) that had not been processed in the decomposition tank 31 is collected and removed by the filter 33. If the high temperature sulfuric acid drainage is recirculated to the retention tank 50, decomposition of peroxosulfuric acid in the sulfuric acid solution accumulated in the retention tank 50 will be promoted; therefore, the sulfuric acid drainage is introduced into the retention tank 50 after the sulfuric acid drainage is cooled by the cooler 34. The sulfuric acid drainage introduced into the retention tank 50 is fed to the electrolyzing device 1 by way of the circulation line 11 as sulfuric acid solution and peroxosulfuric acid is generated by electrolysis, and is then recirculated again through the gas-liquid separation tank 40 to the retention tank 50 by the circulation line 11.

By operation of the present system described above, it is possible to continuously supply a high-temperature functional solution containing high-concentration peroxosulfuric acid to the single-wafer cleaning device 100, which is the application side.

### Fifth Embodiment

Although a configuration including a diaphragm-free electrolyzing device and a retention tank has been explained in the above fourth embodiment, it may be a constitution including a gas-liquid separation tank and retention tank so as to connect to the diaphragm-type electrolyzing device.

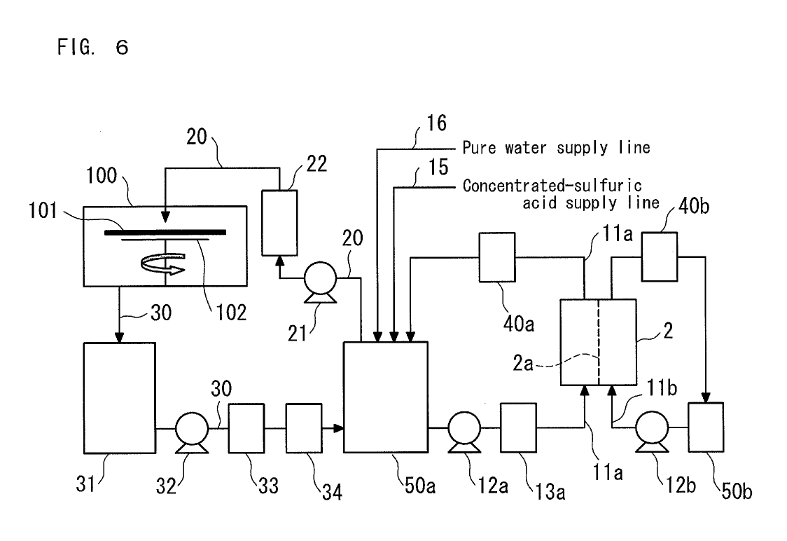

Hereinafter, a fifth embodiment of this constitution will be explained based on FIG. 6.

It should be noted that the same reference symbols are assigned in the fifth embodiment for configurations that are the same as the respective above-mentioned embodiments, and explanations thereof are omitted or abbreviated.

The electrolyzing device 2 has a diaphragm-type configuration, includes an anode and cathode (not illustrated) configured by diamond electrodes, and between this anode and cathode is divided by a diaphragm 2a. The anode side is connected in liquid communication via a circulation line 11a to be able to circulate with a gas-liquid separation tank 40a corresponding to a gas-liquid separation unit of the present invention, and a retention tank 50a corresponding to a retention unit of the present invention. The retention tank 50a is connected via the circulation line 11a to a drainage side of the gas-liquid separation tank 40a, and the sulfuric acid solution subjected to gas-liquid separation by the gas-liquid separation tank 40a is fed to the retention tank 50a and accumulated.

The cathode side of the electrolyzing device 2 is connected in liquid communication via the circulation line 11b to be able to circulate with the retention tank 50b and the gas-liquid separation tank 40b corresponding to a cathode-side gas-liquid separation unit of the present invention. The retention tank 50b is connected via the circulation line 11b to the drainage side of the gas-liquid separation tank 40b, and sulfuric acid solution subjected to gas-liquid separation by the gas-liquid separation tank 40b is fed to the retention tank 50b and is accumulated.

Circulation pumps 12a and 12b feeding the sulfuric acid solution in the retention tank 50a and retention tank 50b to the inlet side of the electrolyzing device 2 are provided in the circulation line 11a and circulation line 11b, respectively. In addition, a cooler 13a that cools the sulfuric acid solution is provided in the circulation line 11a on the anode side at a downstream side of the circulation pump 12a and an upstream side of the inlet side of the electrolyzing device 2, as a unit corresponding to a cooling unit of the present invention. It is thereby possible to regulate to a temperature suited to electrolysis by cooling the sulfuric acid solution on the anode side, which rises in temperature during electrolysis.

It should be noted that a concentrated-sulfuric acid supply line 15 and a pure water supply line 16 are connected to the retention tank 50a to enable liquid communication, whereby it is possible to appropriately supply concentrated sulfuric acid and pure water into the retention tank 50a.

A supply line 20 capable of taking out sulfuric acid solution in the retention tank 50a is connected to the tank, and a single-wafer cleaning device 100 corresponding to an application side of the present invention is provided to a supply end of the supply line 20. A solution feed pump 21 that feeds the sulfuric acid solution in the gas-liquid separation tank 10, and a heating unit 22 that heats the sulfuric acid solution fed by the solution feed pump 21 are provided in the supply line 20 in sequence at an upstream side of the single-wafer cleaning device 100.

Similarly to the above-mentioned respective embodiments, the heating unit 22 has a flow channel 22a having a liquid communication space made of quartz with a thickness (t) of no more than 10 mm, and a near-infrared heater 22b that is arranged so as to irradiate near-infrared rays in the thickness direction onto the flow channel 22a.

One end of the recirculation line 30 is connected to the single-wafer cleaning device 100, and the decomposition tank 31, solution return pump 32, filter 33 and cooler 34 are provided in sequence in the recirculation line 30. At a downstream side thereof, the other end side of the recirculation line 30 is connected to the retention tank 50a.

Next, operation (supply method) of a functional solution supply system composed of the above-mentioned configuration will be explained.

A sulfuric acid solution having a sulfuric acid concentration of 75 to 96% by weight is accumulated in the retention tanks 50a and 50b so as to be able to be supplied through the circulation lines 11a and 11b to the electrolyzing device 2. The sulfuric acid solution is fed by the circulation pumps 12a and 12b, and is introduced through the circulation lines 11a and 11b to the inlet sides of the anode and cathode of the electrolyzing device 2. It should be noted that, after the sulfuric acid solution has been regulated to a temperature suited for electrolysis by the cooler 13, it is introduced to the anode inlet side of the electrolyzing device 2 by the circulation line 11a. In the electrolyzing device 2, current is passed between the anode and cathode by a DC power source that is not illustrated, whereby the sulfuric acid solution introduced into the electrolyzing device 2 is electrolyzed. It should be noted that an oxidizing substance including peroxosulfuric acid and oxygen gas are generated at the anode side, and hydrogen gas evolves at the cathode side in the electrolyzing device 2 by way of the electrolysis. The oxidizing substance and oxygen gas are sent through the circulation line 11a to the gas-liquid separation tank 40a in a state mixed with the sulfuric acid solution, and the oxygen gas is separated. The sulfuric acid solution from which oxygen gas has been separated is fed through the circulation line 11a to the retention tank 50a and is accumulated. On the other hand, the hydrogen gas generated at the cathode side of the electrolyzing device 2 is sent through the circulation line 11b to the gas-liquid separation tank 40b in a state mixed with the sulfuric acid solution, and the hydrogen gas is separated. The sulfuric acid solution from which hydrogen gas has been separated is fed through the circulation line 11b to the retention tank 50b and is accumulated. It should be noted that each gas is discharged to outside of the present system and safely processed by a catalytic device (not illustrated) or the like.

The sulfuric acid solution from which oxygen gas has been separated by the gas-liquid separation tank 40a and accumulated in the retention tank 50a contains peroxosulfuric acid, and furthermore, is repeatedly sent to the anode side of the electrolyzing device 2 through the circulation line 11a, whereby the concentration of peroxosulfuric acid is raised by electrolysis. The sulfuric acid solution from which hydrogen gas has been separated by the gas-liquid separation tank 40b and accumulated in the retention tank 50b is repeatedly sent through the circulation line 11b to the cathode side of the electrolyzing device 2, and subjected to electrolysis.

When the peroxosulfuric acid concentration of the anode-side sulfuric acid solution becomes moderate by way of the above-mentioned electrolysis, a portion of the sulfuric acid solution in the retention tank 50a is fed through the supply line 20 to the heating unit 22 by way of the supply pump 21.

In the heating unit 22, the sulfuric acid solution containing peroxosulfuric acid is heated while passing through the flow channel 22a to a range of 120° C. to 190° C. by the near-infrared heater 22b to make the functional solution. The functional solution is supplied from the heating unit 22 through the supply line 20 to the single-wafer cleaning device 100. The flow rate of the functional solution is regulated so that the transit time from the inlet of the heating unit 22 until used in the single-wafer cleaning device 100 is less than 1 minute.

In the single-wafer cleaning device 100, with the silicon wafer 101 or the like defined as the cleaning target as described above, the resist is effectively stripped and removed by making the above-mentioned functional solution come into contact with the silicon wafer 101 rotating on a rotating table 102.

The functional solution used in cleaning is accumulated through the recirculation line 30 in the decomposition tank 31 as sulfuric acid drainage, and residual organic matter is oxidatively decomposed in the decomposition tank 31.

The sulfuric acid drainage for which residual organic matter has been oxidatively decomposed in the decomposition tank 31 is recirculated through the filter 33 and cooler 34 to the retention tank 50a by way of the solution return pump 32. At this time, SS is collected and removed by the filter 33, and the sulfuric acid drainage is cooled by the cooler 34, then introduced into the retention tank 50a.

It is possible to continuously supply a high-temperature functional solution containing high-concentration peroxosulfuric acid to the single-wafer cleaning device 100, which is the application side, by the operation of this system as well.

Although explanations for the present invention have been made based on the above-mentioned respective embodiments in the foregoing, the present invention is not to be limited to the contents of the above-mentioned embodiments, and appropriate modifications thereto are possible so long as not deviating from the scope of the present invention.

### Example 1

A resist stripping experiments were performed using the functional solution supply system shown in FIG. 3.

As the target cleaning material, a silicon wafer was used with a diameter of 6 inches on which an ion-implanted pattern dosed at 1×10¹⁶ atoms/cm² of As ion at an intensity of 40 keV was formed in a KrF resist with a thickness of 0.8 μm.

The silicon wafer was placed on a rotating table of a single-wafer cleaning device, and the rotating table was made to rotate at a speed of 500 rpm.

For the electrolysis conditions, the fluid temperature of an electrolyzing device inlet was set to 50° C., and the input electrical charge was kept constant at 280 A and the current density at 0.5 A/cm².

The accumulated liquid capacity of the decomposition tank was approximately 3 liter, the liquid capacity of the gas-liquid separation tank was approximately 6 liter, and after sulfuric acid drainage discharged from the single-wafer cleaning device had been retained for about 3 minutes in the decomposition tank, it was recirculated through a cooler to the gas-liquid separation tank, and the sulfuric acid drainage was reused. The sulfuric acid solution temperature in the gas-liquid separation tank was on the order of 60 to 70° C. The supplied amount of functional solution supplied from the gas-liquid separation tank to the single-wafer cleaning device was set to 1000 m liter/min.

A 9 kW near-infrared heater was arranged so as to irradiate infrared rays in the thickness direction to a quartz flow channel with a thickness of 10 mm, thereby configuring the heating unit. The fluid volume from the heating unit inlet until used in the single-wafer cleaning device was about 300 m liter, and the transit time in the present example was approximately 18 seconds. The heater was placed in at a location approximately 1 meter in pipe length from a nozzle outlet of the single-wafer cleaning device, and the near-infrared heater output of the heating unit was controlled to achieve a predetermined temperature by measuring the liquid temperature of the nozzle outlet. The oxidizing substance concentration in the gas-liquid separation tank, oxidizing substance concentration at the nozzle outlet, and time to completely strip and remove resist from a silicon wafer and complete cleaning were measured, when the sulfuric acid concentration was set to 50, 75, 80, 85, 92 and 96% by weight, and the nozzle outlet temperature of the single-wafer cleaning device was set to 100, 130, 160, 180, 190 and 200° C. It should be noted that, after determining the presence or absence of resist residue by visual observation for a wafer for which processing had been completed, it was confirmed by electron microscope that there was no resist residue.

Table 1 shows the oxidizing substance concentration in the gas-liquid separation tank when the present apparatus is continuously operated for several hours and reaching stable operation. Based on this, it was found that the oxidizing substance produced by electrolysis decreases with rising sulfuric acid concentration. This is because, in a case of the sulfuric acid concentration being 50% by weight or more, the peroxosulfuric acid generation efficiency declines with rising sulfuric acid concentration. Table 2 shows the oxidizing substance concentration including peroxosulfuric acid at the nozzle outlet under each condition. When the sulfuric acid concentration rises, the liquid temperature at the nozzle outlet can be raised because the boiling point rises in temperature. However, because the oxidizing substance concentration produced by electrolysis lowers when the sulfuric acid concentration is high, the concentration at the nozzle outlet also lowers. Therefore, when the sulfuric acid concentration and the liquid temperature of the nozzle outlet are too high, the oxidizing substance with peroxosulfuric acid as the main constituent in the electrolyzed fluid almost disappears due to thermal decomposition.

TABLE 1

| Sulfuric acid concentration | Oxidizing substance concentration in |
|---|---|
| [% by weight] | gas-liquid separator [g/L as S₂O₈²⁻] |
| 50 | 23 |
| 75 | 14 |
| 80 | 11 |
| 85 | 10 |
| 92 | 7 |
| 96 | 3 |

TABLE 2

| Sulfuric acid | Oxidizing substance concentration | | | | | |
|---|---|---|---|---|---|---|
| concentration | at nozzle outlet [g/L as S₂O₈²] | | | | | |
| [% by weight] | 100° C. | 130° C. | 160° C. | 180° C. | 190° C. | 200° C. |
| 50 | 21 | x | x | x | x | x |
| 75 | 13 | 12 | 9 | x | x | x |
| 80 | 10 | 10 | 8 | 6 | x | x |
| 85 | 9 | 7 | 4 | 3 | 2 | <1 |
| 92 | 5 | 4 | 3 | 2 | <1 | <1 |
| 96 | 2 | 1 | 1 | <1 | <1 | <1 |

x: boiling point or higher

The time required to completely strip the resist is shown in Table 3. With a sulfuric acid concentration of 50% by weight, it could not be stripped at even if the oxidizing substance concentration was high. In addition, with a nozzle outlet temperature of 100° C., it could not be stripped even if the sulfuric acid concentration was high and oxidizing substance was present. With a sulfuric acid concentration of 96% by weight, the stripping and cleaning effect was poor due to the peroxosulfuric acid almost disappearing at the nozzle outlet.

Therefore, in a case of stripping resist ion-implanted at high concentration, processing for stripping and cleaning is possible in a short time without performing aching with the system of the present invention, by setting the sulfuric acid concentration to 75 to 96% by weight, preferably to 85 to 92% by weight, and setting the liquid temperature for cleaning the electronic materials to 120 to 190° C., and more preferably to 130 to 180° C.

TABLE 3

| Sulfuric acid | | | | | | |
|---|---|---|---|---|---|---|
| concentration | Time required for complete stripping [min.] | | | | | |
| [% by weight] | 100° C. | 130° C. | 160° C. | 180° C. | 190° C. | 200° C. |
| 50 | x | — | — | — | — | — |
| 75 | x | x | Δ | — | — | — |
| 80 | x | Δ | ∘ | ∘ | — | — |
| 85 | x | ∘ | ∘ | ∘ | Δ | x |
| 92 | x | ∘ | ∘ | ∘ | Δ | x |
| 96 | x | Δ | Δ | x | x | x |

∘: Stripping and cleaning are completed within 5 minutes
Δ: Stripping and cleaning are completed from 5 to 20 minutes
x: Stripping and cleaning are not completed even after processing for more than 20 minutes

### Reference Example 1

Using the cleaning system illustrated in Example 1, an experiment was performed under the same conditions other than setting a sulfuric acid concentration of 85% by weight and the nozzle outlet temperature of the single-wafer cleaning equipment to 160° C. Changing the flow rate of the sulfuric acid solution supplied from the gas-liquid separation tank to the single-wafer cleaning equipment to 350, 500, 2000 and 2500 m liter/min., the time taken until stripping and cleaning completed was confirmed minute by minute, and the completion times were compared. It should be noted that, when the flow rate was 2000 and 2500 m liter/min., a heater that was a near-infrared heater 18 kW was specially installed, and the temperature was regulated with the fluid volume from the heater inlet to the nozzle outlet set at approximately 600 m liter. The peroxosulfuric acid concentration at the nozzle outlet and the completion times of stripping and cleaning under the respective flow rate conditions are shown in Table 4.

Based on this, it was found that when the fluid volume supplied to the cleaning target was less than 500 m liter/min., more time was required until stripping and cleaning completed.

TABLE 4

| | | Peroxosulfuric acid | Stripping |
|---|---|---|---|
| | Supplied liquid | concentration | completion |
| | amount [mL/min.] | [g/L as S₂O₈²⁻] | time [min.] |
| Reference | 350 | 2 | 12 |
| Example 1 | | | |
| Reference | 500 | 3 | 4 |
| Example 2 | | | |
| Example 1 | 1000 | 4 | 3 |
| Reference | 2000 | 6 | 2 |
| Example 3 | | | |
| Reference | 2500 | 6 | 2 |
| Example 4 | | | |

### Example 2

Similarly to Reference Example 1, for the three conditions of a sulfuric acid concentration of 80, 85 and 92% by weight, and with the flow rate of sulfuric acid solution supplied from the gas-liquid separation tank to the single-wafer cleaning equipment set to 600 m liter/min., the fluid volume from the heater inlet to the nozzle outlet set to 300 m liter and 600 m liter, it was heated so that the nozzle outlet temperature was 160° C., the time taken until stripping and cleaning completed was confirmed minute by minute, and the completion times were compared, respectively.

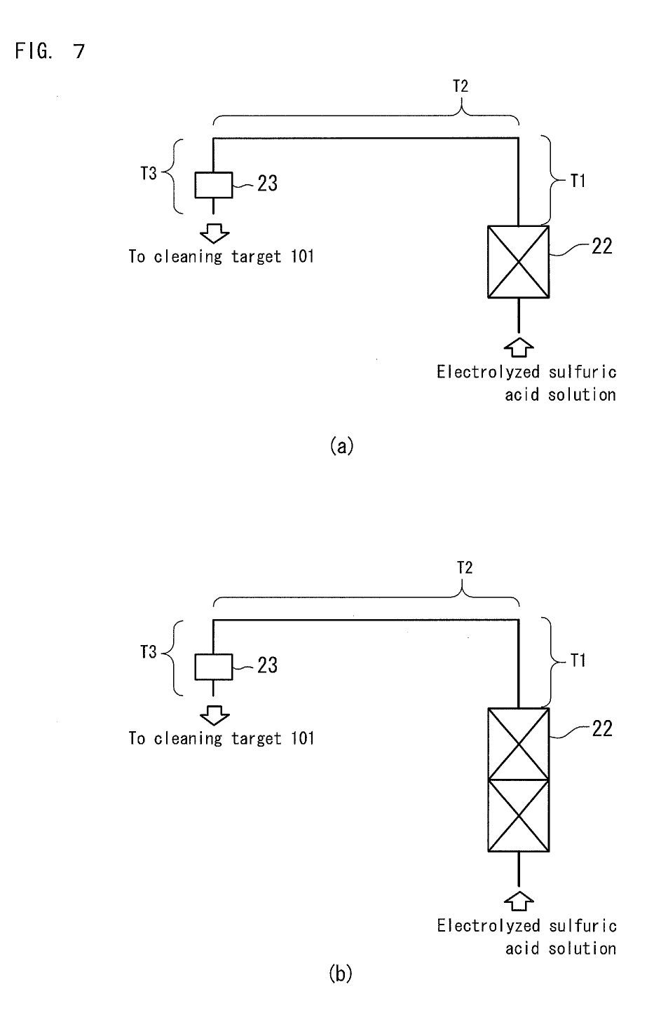

A schematic diagram of the heater used in Example 2 up to the nozzle outlet is shown in FIG. 7. After exiting the heater, it is supplied by a tube to the cleaning unit. In the present invention, it is designed so as to reach the cleaning unit after discharging from the heater on the order of several tens of seconds (less than 1 minute).

The temperature after heating up may be a temperature at which the sulfuric acid in the heater or in the tube at the latter part of the heater does not boil; therefore, the upper limit of the heating temperature is set to less than the boiling point.

Therefore, as properties of the tube, it is necessary to use a tube having high heat resistance, corrosion resistance and PFA (tetrafluorethylene-perfluoroalkylvinyl ether copolymer) or the like can be preferably used, for example.

It should be noted that, the device used herein is one example illustrating from the heater up to the nozzle outlet, and the required cleaning performance is maintained so long as the residence time from the heater inlet until used on the cleaning target is within 40 seconds (preferably within 20 seconds); therefore, the shape of the heater, size of the tube, overall length, and the like are not limited.

In the device of FIG. 7, when from the heater outlet until reaching the nozzle outlet is made to be configured by the tubes T1, T2 and T3, the transit time from the heater inlet until the nozzle outlet, i.e. cleaning unit, can be calculated from the volume of the heater, flow rate of the sulfuric acid solution introduced to the heater, and the inside diameter and length of each of the tubes T1, T2 and T3. It should be noted that 23 in the figure is a temperature sensor.

Examples thereof will be explained below.

Example 1) FIG. 7 (a)

Sulfuric acid solution flow rate 600 m liter/min

Heater volume 250 m liter

T1 inner diameter ⅜ inch, total length 300 mm

T2 inner diameter ¼ inch, total length 700 mm

T3 inner diameter ¼ inch, total length 200 mm

Transit time: 30 seconds

Example 2) FIG. 7 (b)

Sulfuric acid solution flow rate 600 m liter/min

Heater volume 500 m liter

T1 inner diameter ⅜ inch, total length 1000 mm

T2 inner diameter ¼ inch, total length 700 mm

T3 inner diameter ¼ inch, total length 200 mm

Transit time: 1 minute

The heater transit time, peroxosulfuric acid concentration of the nozzle outlet, and completion time of stripping and cleaning under the respective sulfuric acid concentration conditions are shown in Table 5.

It was found that, in the case of the transit time from the heater inlet to the nozzle outlet, i.e. to the cleaning unit, being 1 minute, the peroxosulfuric acid disappeared under any conditions, and the stripping did not complete within 20 minutes. Therefore, it is necessary to clean while peroxosulfuric acid of the required amount remains by shortening the residence time in the heater and the time from the heater outlet until the nozzle outlet, i.e. until feeding to the cleaning unit, as much as possible.

TABLE 5

| | Sulfuric acid concentration [% by weight] | | | | | |
|---|---|---|---|---|---|---|
| | 80 | | 85 | | 92 | |
| Fluid volume from heater | 300 | 600 | 300 | 600 | 300 | 600 |
| inlet to nozzle outlet [m liter] | | | | | | |
| Retention time from heater | 0.5 | 1 | 0.5 | 1 | 0.5 | 1 |
| inlet to nozzle outlet [min.] | | | | | | |
| Peroxosulfuric acid | 5 | <1 | 3 | <1 | 2 | <1 |
| concentration [g/L as S₂O₈²] | | | | | | |
| Stripping completion time | 4 | >20 | 3 | >20 | 5 | >20 |
| [min.] | | | | | | |

### REFERENCE SIGNS LIST

1 Electrolyzing device
2 Electrolyzing device
10 Gas-liquid separation tank
10a Gas-liquid separation tank
10b Gas-liquid separation tank
11 Circulation line
11a Circulation line
11b Circulation line
11c Feed line
11c Return line
12 Circulation pump
12a Circulation pump
12b Circulation pump
13 Cooler
13a Cooler
20 Supply line
21 Supply pump
22 Heater
22a Flow channel
22b Near-infrared heater
30 Recirculation line
31 Decomposition tank
32 Solution return pump
33 Filter
34 Cooler
40 Gas-liquid separation tank
40a Gas-liquid separation tank
40b Gas-liquid separation tank
50 Retention tank
50a Retention tank
50b Retention tank

1. A functional solution supply system, comprising:
an electrolyzing unit that electrolyzes a sulfuric acid solution having a sulfuric acid concentration of 75 to 96% by weight to generate peroxosulfuric acid;
a gas-liquid separation unit that subjects the sulfuric acid solution thus electrolyzed to gas-liquid separation;
a circulation line that causes a portion of the sulfuric acid solution subjected to gas-liquid separation in the gas-liquid separation unit to circulate via the electrolyzing unit to the gas-liquid separation unit;
a supply line that supplies a portion of the sulfuric acid solution subjected to gas-liquid separation in the gas-liquid separation unit to an application side; and
a heating unit that is provided in the supply line and heats the sulfuric acid solution to 120 to 190° C. to make a functional solution,
wherein a transit time after the sulfuric acid solution is introduced to an inlet of the heating unit until being used at the application side is set so as to be less than 1 minute.

2. The functional solution supply system according to claim 1, wherein the electrolyzing unit is constituted to be diaphragm-free type.

3. The functional solution supply system according to claim 1, wherein the electrolyzing unit is constituted to be diaphragm type, the gas-liquid separation unit being connected to an anode side of the electrolyzing unit, and a cathode-side gas-liquid separation unit being connected to a cathode side of the electrolyzing unit.

4. The functional solution supply system according to any one of claims 1 to 3, wherein the gas-liquid separation unit also functions as a retention unit that accumulates the sulfuric acid solution.

5. The functional solution supply system according to any one of claims 1 to 3, further comprising a retention unit that accumulates the sulfuric acid solution subjected to gas-liquid separation in the gas-liquid separation unit,
wherein the circulation line performs the circulation of the sulfuric acid solution accumulated in the retention unit.

6. The functional solution supply system according to claim 5, wherein the supply line performs the supply of the sulfuric acid solution accumulated in the retention unit.

7. The functional solution supply system according to any one of claims 1 to 4, further comprising:
a recirculation line that causes sulfuric acid drainage discharged after use in the application side to recirculate to either one or both the gas-liquid separation unit and the electrolyzing unit; and
a cooling unit that is provided in the recirculation line and cools the sulfuric acid drainage.

8. The functional solution supply system according to claim 5 or 6, further comprising:
a recirculation line that causes sulfuric acid drainage discharged after use in the application side to recirculate to either one or both the retention unit and the electrolyzing unit; and
a cooling unit that is provided in the recirculation line and cools the sulfuric acid drainage.

9. The functional solution supply system according to claim 7 or 8, wherein a decomposition unit that causes the sulfuric acid drainage to be retained and acts to decompose residual organic matter contained in the sulfuric acid drainage is provided on the upstream side of the cooling unit in the recirculation line.

10. The functional solution supply system according to any one of claims 1 to 9, wherein a heat source of the heating unit is a near-infrared heater.

11. The functional solution supply system according to claim 10, wherein the near-infrared heater is disposed so as to irradiate near-infrared rays in a thickness direction relative to a flow channel having a thickness of no more than 10 mm that communicates the sulfuric acid solution, and to heat the sulfuric acid solution by way of radiant heat.

12. The functional solution supply system according to any one of claims 1 to 11, wherein the application side is a single-wafer cleaning system.

13. A functional solution supply method, wherein electrolysis is performed while circulating and subjecting a sulfuric acid solution having a sulfuric acid concentration of 75 to 96% by weight to gas-liquid separation, and a portion of the sulfuric acid solution thus electrolyzed is supplied to an application side after being taken out from the circulation and heated to a temperature of 120 to 190° C., such that a time after initiating the heating until being used is less than 1 minute.
